(19) United States
(12) Patent Application Publication
(10) Pub. No.: US 2025/0342878 A1
(43) Pub. Date: Nov. 6, 2025

(54) GAIN-CELL RANDOM ACCESS MEMORY WITH ENHANCED RETENTION

(71) Applicant: Taiwan Semiconductor Manufacturing Company, Ltd., Hsinchu (TW)

(72) Inventors: Wei Ting Hsieh, Hsinchu (TW); Kuen-Yi Chen, Hsinchu City (TW); Yu-Wei Ting, Taipei City (TW); Yi Ching Ong, Hsinchu (TW); Kuo-Ching Huang, Hsinchu City (TW); Yi-Hsuan Chen, Taoyuan City (TW)

(21) Appl. No.: 19/265,264

(22) Filed: Jul. 10, 2025

Related U.S. Application Data
(63) Continuation of application No. 18/642,897, filed on Apr. 23, 2024.
(60) Provisional application No. 63/599,716, filed on Nov. 16, 2023.

(51) Int. Cl. G11C 11/4096; G11C 5/06; G11C 11/4076; H10B 12/00

(52) U.S. Cl. CPC G11C 11/4096; G11C 5/063; G11C 11/4076; H10B 12/0335; H10B 12/05; H10B 12/315; H10B 12/482; H10B 12/488

(57) ABSTRACT

Some embodiments relate to a memory cell, including: a write transistor on a substrate and comprising a first gate terminal, a first source/drain region, and a second source/drain region coupled to a storage node; a first read transistor on the substrate and comprising a second gate terminal coupled to the storage node and a gate dielectric with a first capacitance; and a capacitor spaced from the first read transistor and the write transistor and further separated from the substrate by the first read transistor and the write transistor, wherein the capacitor is coupled to the storage node and has a second capacitance that is over twice the first capacitance.

### REFERENCE TO RELATED APPLICATIONS

This Application is a Continuation of U.S. application Ser. No. 18/642,897, filed on Apr. 23, 2024, which claims the benefit of U.S. Provisional Application No. 63/599,716, filed on Nov. 16, 2023. The contents of the above-referenced Patent Applications are hereby incorporated by reference in their entirety.

### BACKGROUND

The integrated circuit (IC) manufacturing industry has experienced exponential growth over the last few decades. As ICs have evolved, a variety of different memory storage methods have been developed to fulfill different requirements. One advancement in the evolution of memory storage includes random access memory (RAM). RAM is a form of memory that can be read from or written to in any order.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1E illustrate circuit diagrams of various different embodiments of a gain cell random access memory (GCRAM) cell with a capacitor coupled to a storage node.

FIGS. 2A-2B illustrate a top down view and a three-dimensional view of some embodiments of a GCRAM cell with a capacitor coupled to a storage node and two parallel read transistors.

FIGS. 3A-3B illustrate a top down view and a three-dimensional view of some embodiments of a GCRAM cell with a capacitor coupled to a storage node and two read transistors coupled in series.

FIGS. 4A-4E illustrate cross-sectional views of various different embodiments of a capacitor of a GCRAM cell.

FIGS. 5A-5C illustrate three-dimensional views of some embodiments of crystalline phases of a high-k dielectric that is within a capacitor coupled to a GCRAM cell.

FIGS. 6A-6B illustrate graphs of some embodiments of voltages measured within a GCRAM cell utilizing a capacitor at a storage node compared to voltages measured within a GCRAM cell that does not utilize a capacitor at a storage node.

FIG. 7 illustrates a circuit diagram of some embodiments of a GCRAM array comprising GCRAM cells in a plurality of rows and a plurality of columns.

FIG. 8 illustrates a timing diagram of read and write operations performed by some embodiments of the circuit shown in FIG. 1C.

FIGS. 9-15 illustrate a series of three-dimensional views of some embodiments of a method of forming a GCRAM cell with a capacitor coupled to a storage node.

FIG. 16 illustrates a flowchart of some embodiments of a method of forming a GCRAM cell with a capacitor coupled to a storage node.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A gain-cell random-access memory (GCRAM) cell comprises a write transistor and a read transistor. A first source/drain region of the write transistor is coupled to a write bit line, and a gate of the write transistor is coupled to a write word line. A second source/drain region of the write transistor is coupled to a gate of the read transistor, forming a storage node. Data values are represented by charge at the storage node, which is stored by capacitance at the storage node. Further, the capacitance at the storage node is defined by a capacitance formed by a gate dielectric of the read transistor. During operation, data is written into the GCRAM cell by activating the write transistor, which forms a conductive channel between the write bit line and the storage node and which stores charge at the storage node. The amount of charge is based on the voltage of the write bit line and the capacitance at the storage node.

GCRAM cells offer a smaller footprint (e.g., space the memory cell takes on a substrate) than other types of memory, as they may use as little as two transistors. The smaller footprint results in GCRAM cells forming smaller memory arrays and/or more dense memory arrays than other types of memory. For example, two-transistor or three-transistor GCRAM arrays may have half the size and/or up to twice the density compared to six-transistor static RAM (SRAM) arrays. Accordingly, GCRAM arrays are desirable for a broad array of digital applications, including embedded memory, artificial intelligence applications, machine learning applications, level two caches, level three caches, and so on.

While a CGRAM cell has a number of advantages, the simplest form of the GCRAM cell has a number of disadvantages. Due to a low capacitance at the storage node, the GCRAM cell has a lower charge retention than other memory cells. Further, the read transistor and the write transistor have leakage currents (e.g., subthreshold leakage across the write transistor and gate leakage from either transistor) that may drain or introduce an undesired charge at the storage node. The relatively small charge held at the storage node combined with the leakage currents results in the GCRAM cell having lower charge retention compared to other types of memory. One solution is to introduce one or more refresh circuits to maintain the charge of GCRAM cells in an array. However, the use of refresh circuits increases the space on the substrate dedicated to a GCRAM array, and increases the power used to maintain the array, resulting in a loss of power efficiency. A GCRAM cell that has an enhanced retention time without sacrificing the relatively small footprint of the GCRAM cell is desirable.

The present disclosure provides GCRAM cell with a capacitor vertically stacked with the read transistor and the write transistor. For example, the capacitor may overlie the read and write transistors in back-end-of-line (BEOL) of an integrated circuit (IC), whereas the read and write transistors may be a front-end-of-line (FEOL) of the IC.

The capacitor is coupled to the storage node, in parallel with the capacitance formed by the gate dielectric of the read transistor. This increases the capacitance at the storage node, which increases the charge at the storage node during write. The increase results in a greater retention time, as the leakage current takes longer to drain the charge at the storage node. Further, because the voltage at the storage node is proportional to the charge, the voltage at the gate of the read transistor is maintained at the written value for a longer period of time. In some embodiments, the improved retention is over 100 times the retention time of a GCRAM cell that does not utilize a capacitor. Further, the capacitor does not increase the footprint of the GCRAM cell due to having a lateral area less than a lateral area of the GCRAM cell without the capacitor.

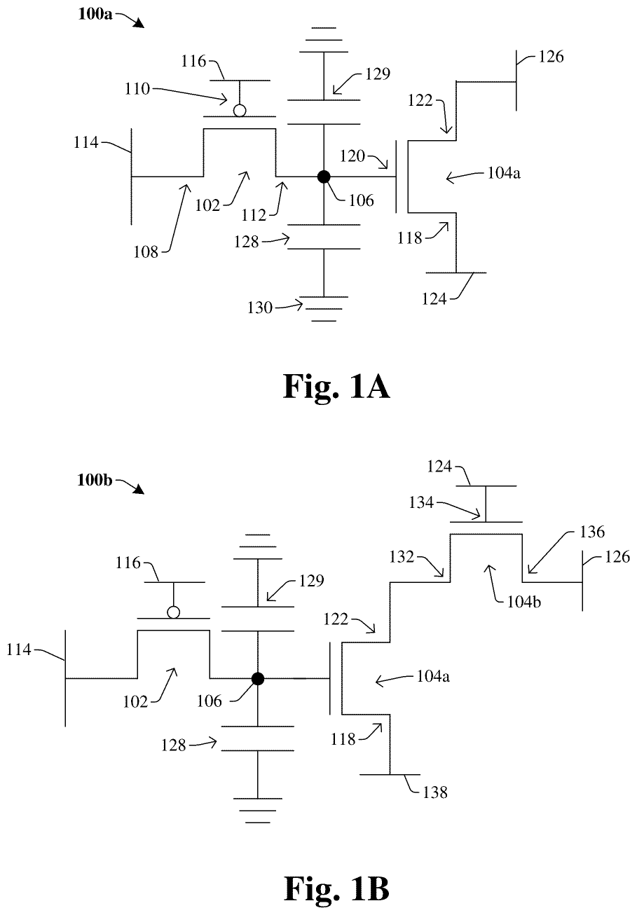

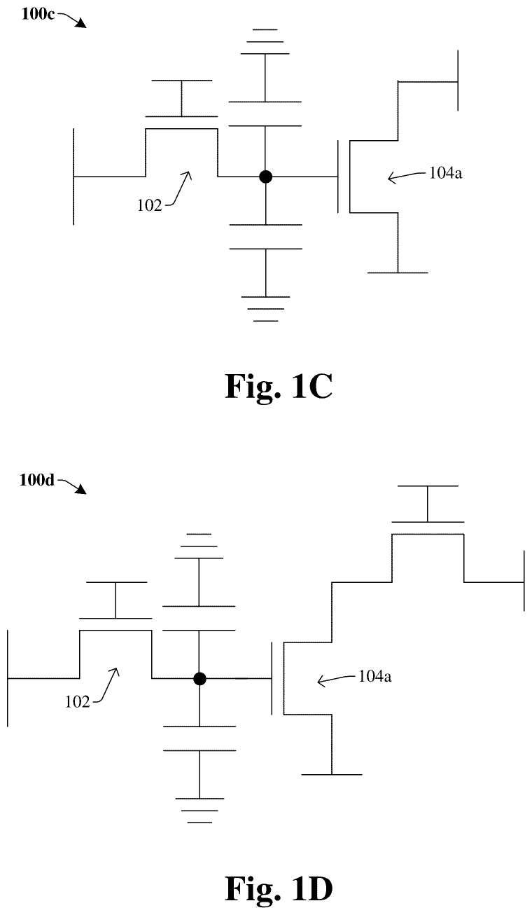

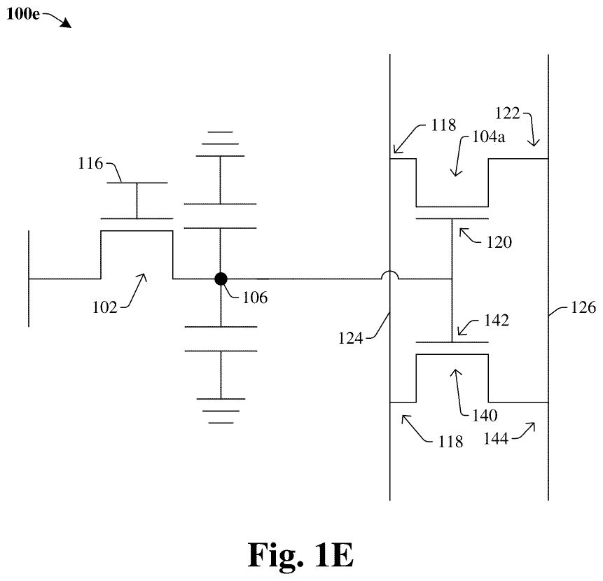

FIGS. 1A-1E illustrate circuit diagrams of various different embodiments of a GCRAM cell with a capacitor coupled to a storage node. FIGS. 1A and IC correspond to a two-transistor embodiment, whereas FIGS. 1B and ID correspond to a three-transistor embodiment.

As shown in the circuit diagram 100a of FIG. 1A, a write transistor 102 and a first read transistor 104a are coupled together at a storage node 106. The write transistor 102 comprises a first source/drain region 108, a first gate terminal 110, and a second source/drain region 112. As used herein, source/drain region(s) may refer to a source region or a drain region, individually or collectively dependent upon the context. The first source/drain region 108 is coupled to a write bit line 114. The first gate terminal 110 is coupled to a write word line 116. The second source/drain region 112 is coupled to the storage node 106. The first read transistor 104a comprises a third source/drain region 118, a second gate terminal 120, and a fourth source/drain region 122. In some embodiments, the third source/drain region 118 is coupled to a read word line 124. In further embodiments, the fourth source/drain region 122 is coupled to a read bit line 126. The second gate terminal 120 is coupled to the storage node 106.

A capacitor 128 is coupled to the storage node 106 and a ground wire 130. In some embodiments, the capacitor 128 is a three-dimensional BEOL capacitor. In other embodiments, the capacitor 128 is a two-dimensional BEOL capacitor comprising a high-k dielectric with a highly symmetrical crystalline phase. In yet other embodiments, the capacitor 128 is a three-dimensional BEOL capacitor comprising a high-k dielectric with a highly symmetrical crystalline phase. The capacitor 128 has a first capacitance. The first read transistor 104a has gate dielectric with a second capacitance 129. The second capacitance 129 is shown as separate from the first read transistor 104a for clarity; the second capacitance 129 is not a separate capacitor and is measured across the gate dielectric of the first read transistor 104a. The first capacitance is over double the second capacitance 129 and the capacitor 128 is electrically coupled in parallel with the second capacitance 129. Hence, the introduction of the capacitor 128 at least triples the capacitance at the storage node 106. The increase in capacitance at the storage node 106 increases the charge stored at the storage node 106 during a write operation. The increase in charge stored results in the leakage currents of the write transistor 102 and the first read transistor 104a taking a longer time to reduce the charge stored. Hence, data retention is increased.

The GCRAM cell can store either a “1” bit or a “0” bit. The “1” bit is stored during a write operation where the write bit line 114 is at a voltage (e.g., V_{dd}) higher than the threshold voltage of the first read transistor 104a. The “0” bit is stored during a write operation where the write bit line 114 is at a voltage (e.g., 0 volts) lower than the threshold voltage of the first read transistor 104a. During the write operation, the write transistor 102 is activated, and charge flows between the write bit line 114 and the storage node 106, resulting in the storage node 106 being held at the voltage of the write bit line 114. After the write operation, the write transistor 102 is deactivated, isolating the write bit line 114 from the storage node 106. Charge remains at the storage node 106, resulting in the storage node 106 maintaining the voltage introduced by the write bit line 114. During a read operation, the stored bit is read by pre-charging the read bit line 126 by applying a voltage (e.g., V_{dd}) for a time interval and then setting the voltage of the read word line 124 to 0. The resulting signal is then read by reading the voltage of the read bit line 126 after a read time interval. If the voltage measured at the read bit line 126 is at or approximately at the applied voltage, then voltage at the storage node is not above the threshold voltage, and the stored voltage is determined to be a “0” bit. If the voltage measured at the read bit line 126 is at or approximately at zero volts, then the voltage at the storage node is above the threshold voltage, and the stored voltage is determined to be a “1” bit.

The voltage at the storage node 106 is based on the voltage supplied by the write bit line 114 during a write operation. The voltage at the storage node 106 is maintained by the presence of the charge held at the storage node 106 and is proportional to the charge held at the storage node 106. Therefore, when the leakage currents (e.g., gate leakage, subthreshold leakage, junction leakage, etc.) from the write transistor 102 and the first read transistor 104a alter the charge held at the storage node 106, the voltage is also affected.

When the voltage at the storage node 106 is at or near the threshold voltage of the first read transistor, noise in an IC accommodating the GCRAM cell may make the outcome of the read operation uncertain. That is, determination of the stored signal is dominated by noise if the leakage current brings the held voltage near the threshold voltage. The time it takes for the leakage currents to introduce or take away enough charge to bring the voltage at the storage node 106 to the threshold voltage is known as the retention time of the GCRAM cell. The increase in capacitance and increase in charge at the storage node 106 from the introduction of the capacitor 128 results in a greater retention time. This may further reduce the footprint of a GCRAM array by reducing the amount of refresh circuitry used to maintain storage-node charge. The reduction in refresh circuitry may further reduce power usage.

As shown in the circuit diagram 100b of FIG. 1B, in some embodiments, a second read transistor 104b is coupled to the first read transistor 104a. The second read transistor 104b has a fifth source/drain region 132 coupled to the fourth source/drain region 122, a third gate terminal 134 coupled to the read word line 124, and a sixth source/drain region 136 coupled to the read bit line 126. The third source/drain region 118 is coupled to a reset line 138 which is grounded during read operations.

The GCRAM cell is read during a read operation by applying a voltage (e.g., V_{dd}) to the read bit line 126 and a high voltage to the read word line 124 to select the GCRAM cell from the GCRAM array. The high voltage is high in that it exceeds a threshold voltage of the second read transistor 104b. Then the voltage on the read bit line 126 is measured. If the voltage measured at the read bit line 126 is at or approximately at the applied voltage, then voltage at the storage node is not above the threshold voltage, and the stored voltage is determined to be a “0” bit. If the voltage measured at the read bit line 126 is at or approximately at zero volts, then the voltage at the storage node is above the threshold voltage, and the stored voltage is determined to be a “1” bit.

As shown in the circuit diagrams 100c, 100d of FIG. 1C and FIG. 1D, in some embodiments, the circuits depicted in FIGS. 1A and 1B have an N-type write transistor 102. The write transistor 102 and the first read transistor 104a are or comprise P-type transistors or N-type transistors. In some embodiments, the write transistor 102 and the first read transistor 104a are a same transistor type (e.g., both N-type transistors). In other embodiments, as depicted in FIGS. 1A and 1B, the write transistor 102 and the first read transistor 104a are different transistor types (e.g., the write transistor 102 is a P-type transistor and the first read transistor 104a is an N-type transistor).

As shown in the circuit diagram 100e of FIG. 1E, in some embodiments, in some embodiments, the GCRAM cell may comprise multiple transistors in parallel between the read bit line 126 and the read word line 124, the multiple transistors comprising the first read transistor 104a and a parallel transistor 140. The second gate terminal 120 of the first read transistor 104a and a fourth gate terminal 142 of the parallel transistor 140 are coupled to the storage node 106 in parallel. The parallel transistor 140 has a seventh source/drain region 144 coupled to the read bit line 126 in parallel with the fourth source/drain region 122 of the first read transistor 104a. The first read transistor 104a and the parallel transistor 140 share the third source/drain region 118.

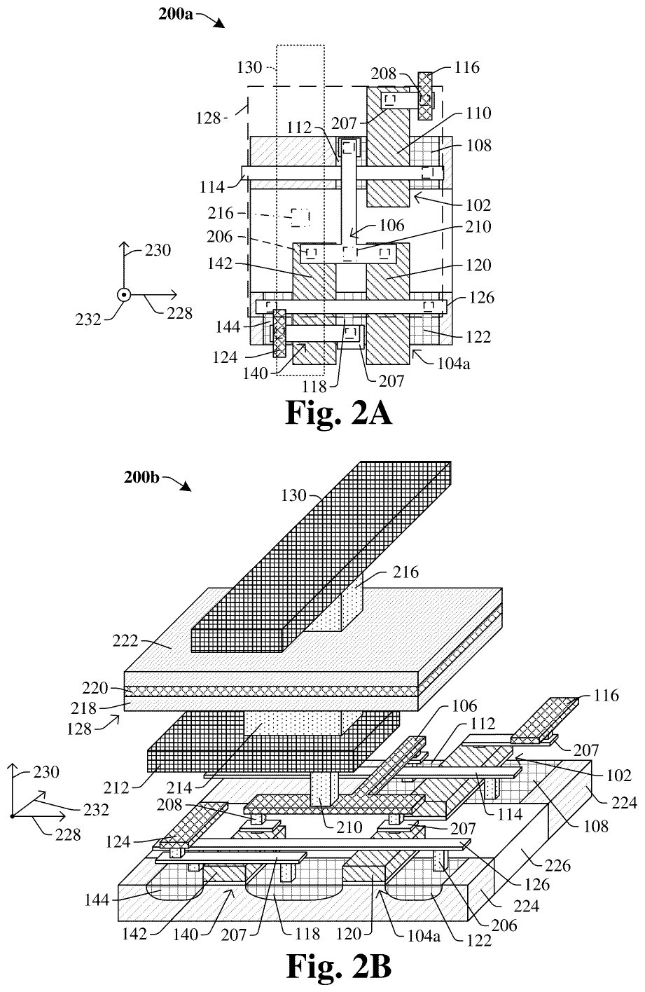

FIGS. 2A-2B illustrate a top down view 200a and a three-dimensional view 200b of some embodiments of a GCRAM cell with a capacitor coupled to the storage node and two parallel read transistors. The GCRAM cell shown in FIGS. 2A-2B is one embodiment of the circuit shown in FIG. 1E. FIGS. 2A and 2B are described concurrently.

The second gate terminal 120 of the first read transistor 104a and a fourth gate terminal 142 of the parallel transistor 140 are coupled to the storage node 106 by a plurality of contacts 206 (shown in phantom in FIG. 2A) and a first via level 208 (see FIG. 2B). The seventh source/drain region 144 of the parallel transistor 140 is coupled to the read bit line 126 in parallel with the fourth source/drain region 122 of the first read transistor 104a. The first read transistor 104a and the parallel transistor 140 share the third source/drain region 118.

The plurality of contacts 206 further extends to the first gate terminal 110 and the first, second, third, and fourth source/drain regions 108, 112, 118, 122. The plurality of contacts 206 extend to a first wire level that comprises the write bit line 114, the read bit line 126, and interconnects 207. The read bit line 126 and the write bit line 114 extend in a first direction 228. The first via level 208 extends between the first wire level and a second wire level that comprises the storage node 106. In some embodiments, the write word line 116 and/or the read word line 124 is/are on the second wire level. The write word line 116 and the read word line 124 extend in a second direction 230 perpendicular to the first direction 228.

The capacitor 128 (shown in phantom in FIG. 2A) overlies the storage node 106 in a third direction 232 and is coupled to the storage node 106 by a second via level 210. The capacitor 128 further overlies the write transistor 102, the first read transistor 104a, and the parallel transistor 140. In some embodiments, a third wire level 212 extends between the capacitor 128 and the storage node 106. The third wire level 212 functions as a landing for a third via level 214 that extends between the third wire level 212 and the capacitor 128. The capacitor 128 is further coupled to the ground wire 130 by a fourth via level 216.

In some embodiments, the capacitor 128 comprises a lower electrode 218, a high-k dielectric 220, and an upper electrode 222. In alternative embodiments, the high-k dielectric 220 is replaced with a dielectric that does not have a high k. The lower electrode 218 and the upper electrode 222 comprise a conductive material, such as aluminum (Al), titanium (Ti), tantalum (Ta), gold (Au), platinum (Pt), tungsten (W), nickel (Ni), iridium (Ir), titanium nitride (TiN), tantalum nitride (TaₓN_{y}), iridium oxide (IrO₂), a negatively doped polysilicon material, a positively doped polysilicon material, or the like. The high-k dielectric comprises one or more of a metal oxide (e.g., hafnium oxide (HfₓO_{y}, HfO₂), hafnium silicon oxide (HfₓSi_{y}O_{z}), hafnium aluminum oxide (HfₓAl_{y}O_{z}), hafnium gadolinium oxide (HfₓGd_{y}O_{z}), hafnium zirconium oxide (HfₓZr_{y}O_{z}), hafnium lanthanum oxide (HfₓLa_{y}O_{z}), hafnium strontium oxide (HfₓSr_{y}O_{z}), hafnium yttrium oxide (HfₓY_{y}O_{z}), strontium titanium oxide (STO, SrTiO₃), zirconium oxide (ZrO₂), titanium oxide (TiO₂), barium titanate (BaTiO₃), etc.), a metal oxynitride (e.g., hafnium oxynitride (HfON), zirconium oxynitride (ZrON), etc.), or the like.

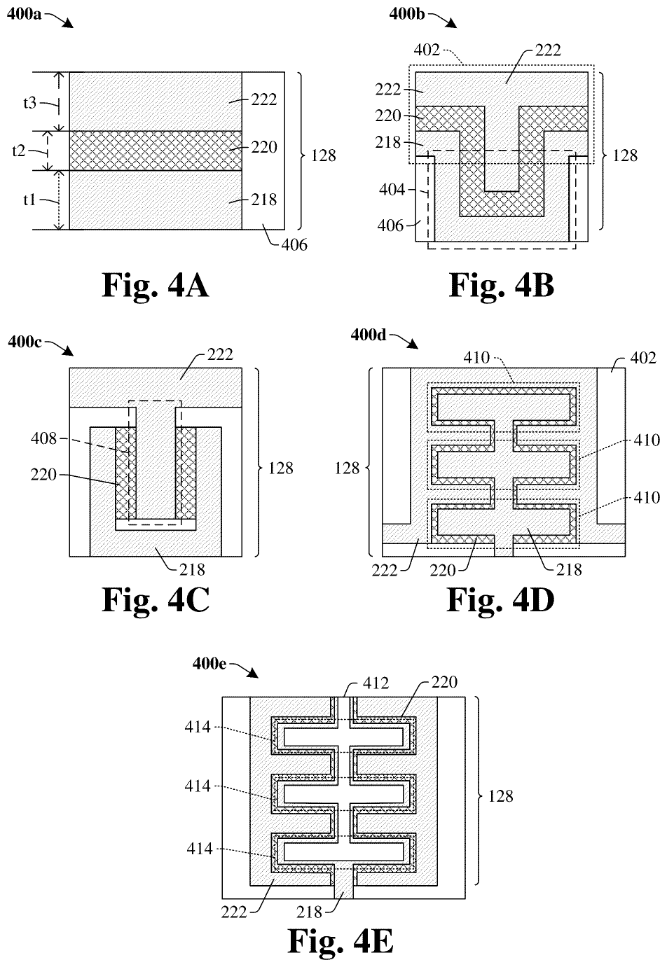

In some embodiments, the high-k dielectric has a highly symmetrical crystalline phase, such as a cubic phase, a tetragonal phase, or a hexagonal phase. High-k dielectric materials with a highly symmetric crystalline phase have a greater dielectric constant than high-k dielectric materials without a highly symmetric crystalline phase. The dielectric constant of the high-k dielectric is dependent upon the material the high-k dielectric is made of and the symmetry of the crystalline phase of the material. In some embodiments, the high-k dielectric 220 has a dielectric constant greater than 35. The dielectric constant being greater than 35 results in the capacitor 128 having a capacitance over twice as great as the capacitance across the gate dielectrics of the first read transistor 104a and the parallel transistor 140 without increasing the area of the capacitor beyond 60 to 80% of the area of the GCRAM cell. In some embodiments, if the dielectric constant is less than 35, the capacitor 128 would have a lower capacitance, reducing the charge held at the storage node and the resulting retention time of the GCRAM cell. The capacitance can be increased further when utilizing a three-dimensional capacitor configuration (see FIGS. 4B-4E).

In some embodiments, the write transistor 102, the first read transistor 104a, and the parallel transistor 140 are FEOL devices embedded in a substrate 224. The write transistor 102 and the first read transistor 104a are further separated from one another by an isolation region 226. In some embodiments, the FEOL devices are or comprise one or more of a planar FET, a FinFET, a gate-all-around (GAA) device, etc. In some embodiments, the first read transistor 104a, the write transistor 102, and the second read transistor 104b collectively span a first area when viewed top down, and wherein the capacitor 128 spans a second area when viewed top down that is between 60% and 80% of the first area.

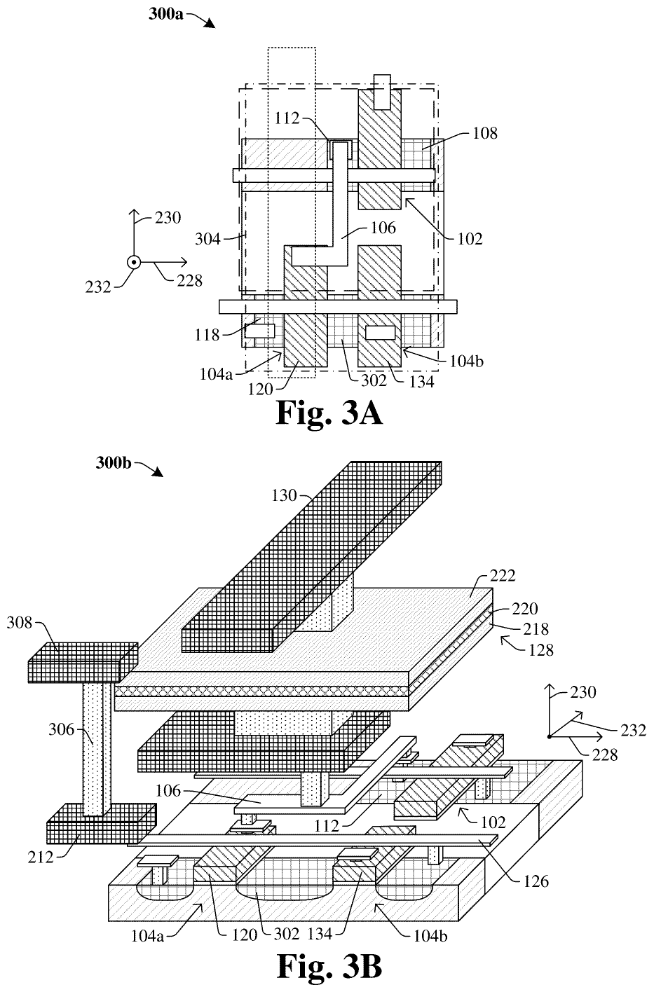

FIGS. 3A-3B illustrate a top down view 300a and a three-dimensional view 300b of some embodiments of a GCRAM cell with a capacitor coupled to the storage node and two read transistors coupled in series. The GCRAM cell shown in FIGS. 3A-3B is one embodiment of the circuit shown in FIG. 1B. FIG. 3A and FIG. 3B are described concurrently. The write word line 116 and read word line 124 are not shown in FIGS. 3A and 3B to enhance clarity.

In some embodiments, the first read transistor 104a and the second read transistor 104b are coupled in series. In further embodiments, the fourth source/drain region 122 of the first read transistor 104a and the fifth source/drain region 132 of the second read transistor 104b overlap one another, forming a shared source/drain region 302. The shared source/drain region 302 extends from a channel of the first read transistor 104a to a channel of the second read transistor 104b. The storage node 106 is coupled to the second source/drain region 112 of the write transistor 102 and the second gate terminal 120 of the first read transistor 104a, but is not coupled to the third gate terminal 134 of the second read transistor 104b. The third gate terminal 134 of the second read transistor 104b is instead coupled to the read word line 124.

In some embodiments, the first read transistor 104a, the write transistor 102, and the second read transistor 104b are within a first GCRAM cell region 304 that has a first area measured parallel to an upper surface of the substrate 224. The capacitor 128 has a second area measured parallel to an upper surface of the substrate 224. The second area is between 60% and 80% of the first area. In some embodiments, the GCRAM cell region 304 has outer boundaries in the second direction 230 between an outermost sidewall of the first write transistor 102 and an outermost sidewall of the first read transistor 104a, and is confined in the first direction between an outer edge of the first source/drain region 108 and an outer edge of the third source/drain region 118.

The area of the capacitor 128 being lower than the area of the first GCRAM cell region 304 results in the remaining area on the level of the capacitor 128 being available for routing vias (e.g., a first via 306) between the capacitor 128 and other capacitors in the GCRAM cell array. The availability of space to route the first via 306 around the capacitor 128, and over the first GCRAM cell region 304, increases the flexibility of implementation while lowering the footprint in embodiments where routing between capacitors is used. The first via 306 is level with the capacitor 128 and extends between the third wire level 212 and a fourth wire level 308 that is level with the ground wire 130.

FIGS. 4A-4E illustrate cross-sectional views 400a, 400b, 400c, 400d, 400e of various different embodiments of a capacitor of the GCRAM cell with varying configurations.

As shown in FIG. 4A, in some embodiments, the capacitor 128 has a planar layout. The lower electrode 218 has a first thickness t1 between approximately 0.1 nanometers and 30 nanometers, between approximately 1 nanometer and 20 nanometers, or another similar range. The high-k dielectric 220 has a second thickness t2 between approximately 1 nanometer and 10 nanometers, between approximately 2 nanometers and 8 nanometers, or another similar range. The upper electrode 222 has a third thickness t3 between approximately 0.1 nanometers and 30 nanometers, between approximately 1 nanometer and 20 nanometers, or another similar range. The capacitor 128 and other components of the GCRAM cell over the substrate (sec, e.g., 224 of FIG. 2B) are surrounded by an interlayer dielectric 406. The interlayer dielectric 406 was not shown in previous figures to maintain clarity.

As shown in FIG. 4B, in some embodiments, the capacitor 128 has a three-dimensional layout with a protrusion 404 extending from a base portion 402 of the upper electrode 222. The addition of the protrusion 404 extends the surface area of the electrodes in the capacitor 128, increasing the capacitance. In some embodiments, the high-k dielectric 220 does not have a highly symmetrical crystalline phase, as the three-dimensional layout increases the capacitance of the capacitor 128 to be greater than double the capacitance of the first read transistor (see 104a of FIG. 1A) and the parallel transistor (see 140 of FIG. 2A) if present.

As shown in FIG. 4C, in some embodiments, the capacitor 128 has a three-dimensional layout with a cylindrical configuration, where the lower electrode 218 surrounds a cylindrical protrusion 408 from the upper electrode 222. As shown in FIG. 4D, in some embodiments, the capacitor 128 has a three-dimensional layout with a multi-fin configuration, where the lower electrode 218 comprises a plurality of fins 410 that are surrounded by the upper electrode 222. As shown in FIG. 4E, in some embodiments, the capacitor 128 has three-dimensional layout with a multi-finger configuration, where the lower electrode 218 surrounds a dielectric structure 412 comprising a plurality of protrusions 414, and the upper electrode 222 also surrounds the plurality of protrusions 414.

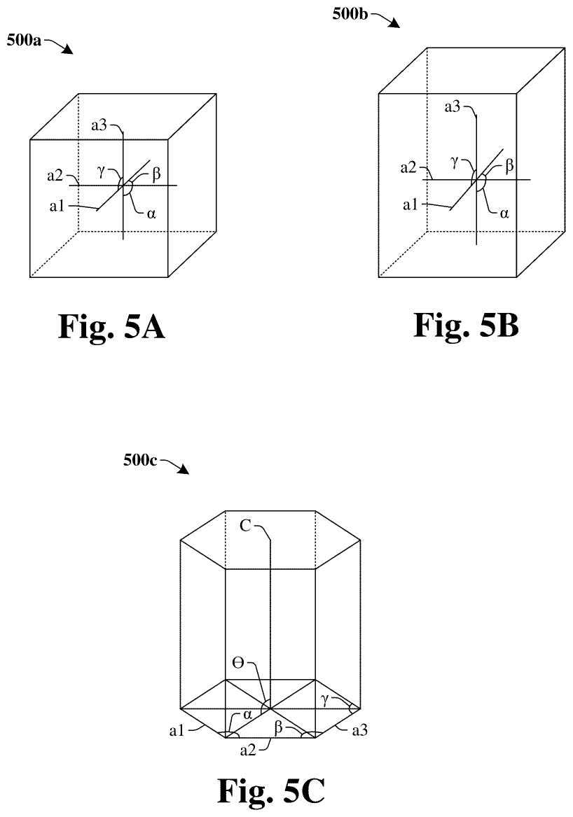

FIGS. 5A-5C illustrate a plurality of three-dimensional views 500a, 500b, 500c of some embodiments of crystalline phases of a high-k dielectric that is within the capacitor coupled to the GCRAM cell. In some embodiments, the highly symmetric crystalline phase comprises one of a cubic phase, a tetragonal phase, or a hexagonal phase.

As shown in the three-dimensional view 500a of FIG. 5A, in some embodiments, the high-k dielectric (sec, e.g., 220 of FIG. 2B or 3B) has a cubic phase. In the cubic phase, a first lattice constant al, a second lattice constant a2, and a third lattice constant a3 have equal lengths. The lattice constants a1, a2, a3 show the length of the unit cell along different axes of repetition. In the cubic phase, a first lattice angle α, a second lattice angle β, and a third lattice angle γ are equal to 90 degrees. The lattice angles α, β, γ show the angles between the lattice constants of the unit cell.

As shown in the three-dimensional view 500b of FIG. 5B, in some embodiments, the high-k dielectric (see, e.g., 220 of FIG. 2B or 3B) has a tetragonal phase. In the tetragonal phase, the first lattice constant a1 and the second lattice constant a2 have equal lengths, and the third lattice constant a3 has a different length from the first lattice constant a1 and the second lattice constant a2. Further, the first lattice angle α, the second lattice angle β, and the third lattice angle γ of a unit cell in the tetragonal phase are equal to 90 degrees.

As shown in the three-dimensional view 500c of FIG. 5C, in some embodiments, the high-k dielectric (sec, e.g., 220 of FIG. 2B or 3B) has a hexagonal phase. In the hexagonal phase, the first lattice constant al, the second lattice constant a2, and the third lattice constant a3 have equal lengths, and a fourth lattice constant C has a different length from the first lattice constant a1. Further, the first lattice angle α, the second lattice angle β, and the third lattice angle γ of a unit cell in the hexagonal phase are equal to 120 degrees, while a fourth lattice angle Θ is equal to 90 degrees.

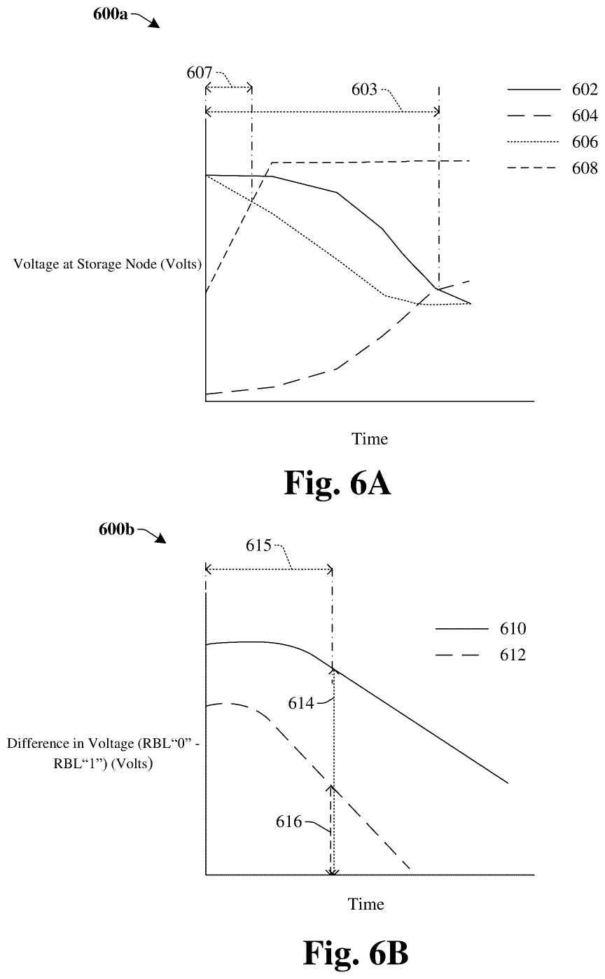

FIGS. 6A-6B illustrate graphs 600a, 600b of some embodiments of voltages measured within the GCRAM cell utilizing the capacitor at the storage node compared to voltages measured within a GCRAM cell that does not utilize the capacitor.

As shown in the graph 600a of FIG. 6A, in embodiments with a capacitor (see 128 of FIG. 1A) at the storage node (see 106 of FIG. 1A), a first voltage 602 measured at the storage node when a “1” bit is written to the GCRAM cell is above a second voltage 604 measured at the storage node when a “0” bit is written to the GCRAM cell for a first time period 603. Further, in embodiments without a capacitor (see 128 of FIG. 1A) at the storage node (see 106 of FIG. 1A), a third voltage 606 measured at the storage node when a “1” bit is written to the GCRAM cell is above a fourth voltage 608 measured at the storage node when a “0” bit is written to the GCRAM cell for a second time period 607. That is, after the second time period 607, the voltage measured at the storage node (sec 106 of FIG. 1A) in embodiments without a capacitor is no longer indicative of the initially stored value. The first time period 603 is larger than the second time period 607. In some embodiments where the first capacitance of the capacitor (see 128 of FIG. 1A) is over double the second capacitance that is measured across the gate dielectric of the first read transistor, the first time period 603 is over 100 times the second time period 607.

As shown in the graph 600b of FIG. 6B, in embodiments with a capacitor (see 128 of FIG. 1B) at the storage node (see 106 of FIG. 1B) and a second read transistor (see 104b of FIG. 1B), a first difference in voltage measurements 610 performed at the read bit line when a “1” bit is stored and when a “0” bit is stored is at a first value 614 after a first time period 615. The difference in voltage measurements 610 is found by measuring the voltage of the read bit line (sec 126 of FIG. 1B) at multiple time intervals when a “1” bit is stored at the storage node and is not refreshed. The voltage at the read bit line (see 126 of FIG. 1B) when a “0” bit is stored at the storage node is then measured at multiple time intervals. The resulting “0” bit voltage measurements are subtracted from the “1” bit voltage measurements, resulting in the difference in voltage measurements 610 shown in the graph 600b.

In embodiments without a capacitor (see 128 of FIG. 1A) at the storage node (see 106 of FIG. 1A), a second difference in voltage measurements 612 performed at the read bit line when a “1” bit is stored and when a “0” bit is stored is at a second value 616 after a first time period 615. In both embodiments, the difference in voltage between a “1” bit reading and a “0” bit reading decays over time. However, in embodiments with the capacitor (see 128 of FIG. 1A) coupled to the storage node (see 106 of FIG. 1A), the initial difference in voltage between the two measurements is greater than the difference in voltage measured in embodiments without the capacitor (sec 128 of FIG. 1A). Further, in embodiments with the capacitor (see 128 of FIG. 1A) coupled to the storage node (see 106 of FIG. 1A), the difference in voltage between the two measurements at later measurement intervals is also greater than the difference in voltage measured in embodiments without the capacitor (see 128 of FIG. 1A). The difference in voltage measurements 610 of the embodiments with the capacitor (see 128 of FIG. 1A) decays at a slower rate than the difference in voltage measurements 612 of the embodiments without the capacitor (sec 128 of FIG. 1A).

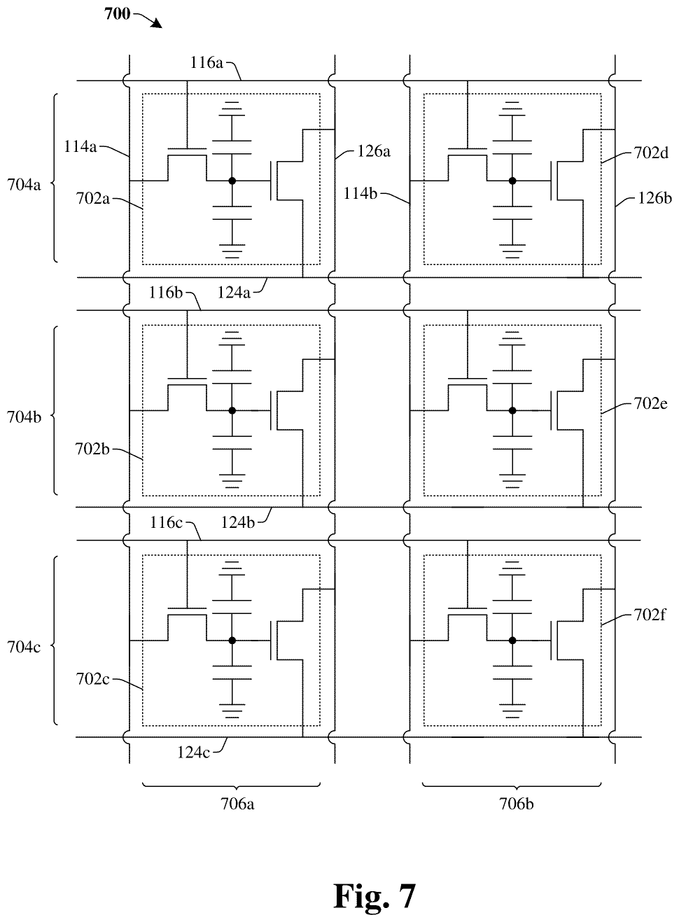

FIG. 7 illustrates a circuit diagram 700 of some embodiments of a GCRAM array comprising GCRAM cells in a plurality of rows and a plurality of columns.

The GCRAM array comprises a plurality of GCRAM cells 702a-702f in a plurality of rows 704a, 704b, 704c and columns 706a, 706b. The GCRAM cells in the first column 706a (e.g., a first GCRAM cell 702a, a second GCRAM cell 702b, and a third GCRAM cell 702c) are coupled to a first write bit line 114a and a first read bit line 126a. The GCRAM cells in the second column 706b (e.g., a fourth GCRAM cell 702d, a fifth GCRAM cell 702e, and a sixth GCRAM cell 702f) are coupled to a second write bit line 114b and a second read bit line 126b. The GCRAM cells in the first row 704a (e.g., the first GCRAM cell 702a and the fourth GCRAM cell 702d) are coupled to a first write word line 116a and a first read word line 124a. The GCRAM cells in the second row 704b (e.g., the second GCRAM cell 702b and the fifth GCRAM cell 702e) are coupled to a second write word line 116b and a second read word line 124b. The GCRAM cells in the third row 704c (e.g., the third GCRAM cell 702c and the sixth GCRAM cell 702f) are coupled to a third write word line 116c and a third read word line 124c.

The first GCRAM cell 702a is shown coupled to a first write bit line 114a, a first write word line 116a, a first read bit line 126a, and a first read word line 124a. A second GCRAM cell 702b and a third GCRAM cell 702c are in a first column 706a of a plurality of columns with the first GCRAM cell 702a. The second GCRAM cell 702b and the third GCRAM cell 702c are coupled to the first write bit line 114a and the first read bit line 126a, but the second GCRAM cell 702b is coupled to a second read word line 116b and a second write word line 124b, while the third GCRAM cell 702c is coupled to a third read word line 116c and a third write word line 124c. The first GCRAM cell 702a is in a first row 704a of a plurality of rows with a fourth GCRAM cell 702d. The first GCRAM cell 702a and the fourth GCRAM cell 702d are coupled to the first write word line 116a and the first read word line 124a, but the fourth GCRAM cell 702d is coupled to a second write word line 116b and a second read word line 124a.

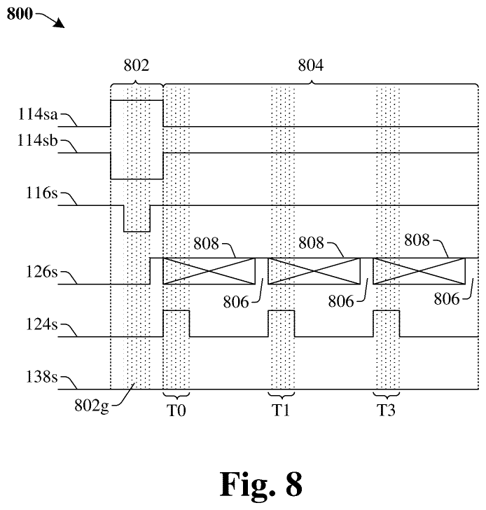

FIG. 8 illustrates a timing diagram 800 of read and write operations performed by some embodiments of the circuit shown in FIG. 1C.

The timing diagram 800 shows the signals that are provided to the GCRAM cell during operation. When writing a “1” bit, the write bit line (see 114 of FIG. 1B) is driven to a high voltage (e.g., Vdd) during a write operation 802, as shown by a write bit line signal 114sa. When writing a “0” bit, the write bit line (see 114 of FIG. 1B) is driven to a low voltage (e.g., 0 volts) during the write operation 802, as shown by a second write bit line signal 114sb. In some embodiments, where the write transistor (see 102 of FIG. 1B) is a p-type transistor, the write word line (see 116 of FIG. 1B) is driven to a low voltage (e.g., −Vdd) below a threshold voltage of the write transistor (see 102 of FIG. 1B) as shown in a write word line signal 116s, coupling the write bit line (see 114 of FIG. 1B) to the storage node (see 106 of FIG. 1B) for a time period 802g. The write word line signal 116s is then returned to its original voltage (e.g., 0 volts) until another write operation is called for.

Before read operations 804, the read bit line (see 126 of FIG. 1B) is driven to a high voltage (e.g., Vdd), as shown in the pre-charge phases 806 of a read bit line signal 126s. The read operations 804 begin with the read word line (see 124 of FIG. 1B) being driven to a high voltage (e.g., Vdd) for a time period TO, as shown by a read word line signal 124s. The read word line signal 124s rising above the threshold voltage of the second read transistor (see 104b of FIG. 1B) couples the read bit line signal 126s to the fourth source/drain region 122 of the first read transistor (see 104a of FIG. 1B). Subsequently, if a “1” bit is stored at the storage node (see 106 of FIG. 1B), the read bit line signal 126s will be driven to a low voltage (e.g., 0 volts) for the period 808 due to being coupled to the reset line (see 138 of FIG. 1B), which is held at 0 volts during the read operation 804. If a “0” bot is stored at the storage node (see 106 of FIG. 1B), the read bit line signal 126s will remain at a high voltage (e.g., Vdd) for the period 808, as the first read transistor will not be activated and the reset line (see 138 of FIG. 1B) would not be coupled to the read bit line (see 126 of FIG. 1B). The read operation may be repeated in time periods T1 and T2, after another pre-charge phase returns the read bit line signal 126s to a high voltage (e.g., Vdd).

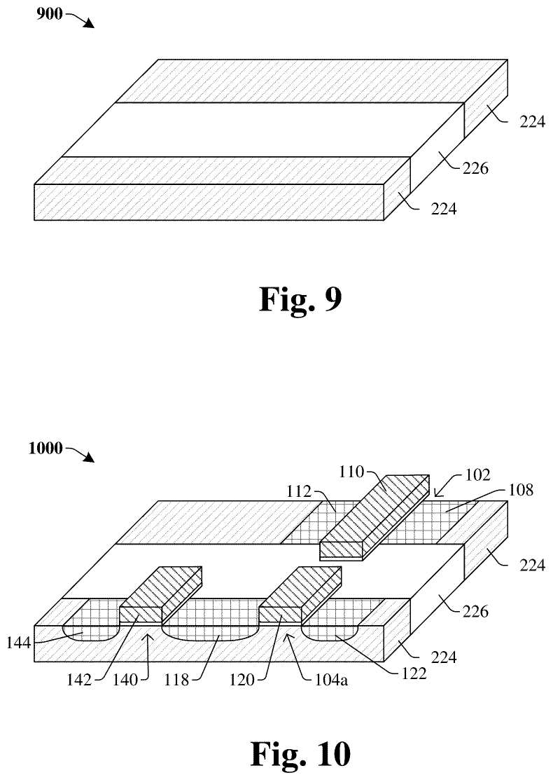

FIGS. 9-15 illustrate a series of three-dimensional views 900-1500 of some embodiments of a method of forming a GCRAM cell with a capacitor coupled to the storage node. Although FIGS. 9-15 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in a three-dimensional view 900 of FIG. 9, the isolation region 226 is formed within the substrate 224. In some embodiments, the isolation region 226 is a shallow trench isolation region, a deep trench isolation region, or another type of isolation region. In some embodiments, the substrate 224 is or comprises silicon, sapphire, the like, or any combination of the foregoing. In some embodiments, the isolation region 226 is or comprises an insulative material, such as silicon oxide (SiO₂), silicon nitride (Si₃N₄), or the like. The isolation region 226 is formed by etching an opening into the substrate, and then subsequently filling the opening with the insulative material.

As shown in the three-dimensional view 1000 of FIG. 10, the write transistor 102, the first read transistor 104a, and the parallel transistor 140 are formed on the substrate 224. The transistors (e.g., the write transistor 102, the first read transistor 104a, and the parallel transistor 140) are formed by forming gate dielectrics and the gate terminals (e.g., the first gate terminal 110, the second gate terminal 120, and the fourth gate terminal 142) stacked over channel regions in the substrate 224. The gate dielectrics and the gate terminals are formed by depositing a conformal gate dielectric layer and a conformal gate material (e.g., polysilicon) layer over the substrate 224. The conformal gate dielectric layer and the conformal gate material layer are then patterned to form the gate dielectrics and the gate terminals. After forming the gate dielectrics and the gate terminals, dopants are implanted into the substrate 224 to form the source/drain regions (e.g., the first, second, third, fourth, and seventh source/drain regions 108, 112, 118, 122, 144). In some embodiments, additional gate replacement steps are performed to form gate terminals that comprise conductive metals or metal nitrides, such as tantalum (Ta), titanium (Ti), titanium nitride (TiN), or the like. In some embodiments, the first gate terminal 110, the second gate terminal 120, and the fourth gate terminal 142 extend over the isolation region 226.

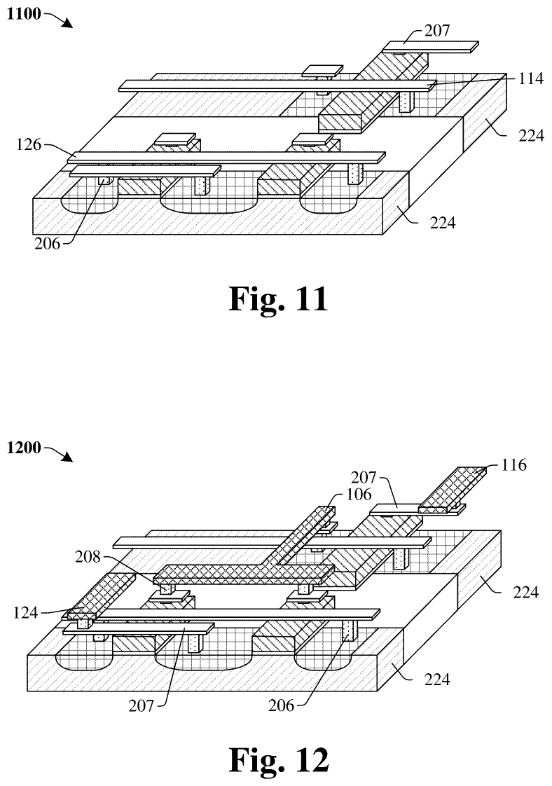

As shown in the three-dimensional view 1100 of FIG. 11, the plurality of contacts 206 and the first wire level are formed over the substrate 224. In some embodiments, the first wire level comprises the read bit line 126, the write bit line 114, and interconnects 207. In some embodiments, the plurality of contacts 206 and/or the first wire level comprise a conductive material, such as aluminum (Al), titanium (Ti), tantalum (Ta), gold (Au), platinum (Pt), tungsten (W), nickel (Ni), iridium (Ir), titanium nitride (TiN), tantalum nitride (TaN), a negatively doped polysilicon material, a positively doped polysilicon material, or the like. In some embodiments, the plurality of contacts 206 and the first wire level are formed using a dual damascene process, one or more single damascene processes, or the like.

As shown in the three-dimensional view 1200 of FIG. 12, the first via level 208 and the second wire level are formed over the substrate 224. The second wire level comprises the storage node 106. In some embodiments, the second wire level further comprises the read word line 124 and the write word line 116. In some embodiments, the first via level 208 and the second wire level are or comprise a same material as the plurality of contacts 206 and/or as the first wire level. In some embodiments, the first via level 208 and the second wire level are formed using a dual damascene process, one or more single damascene processes, or the like.

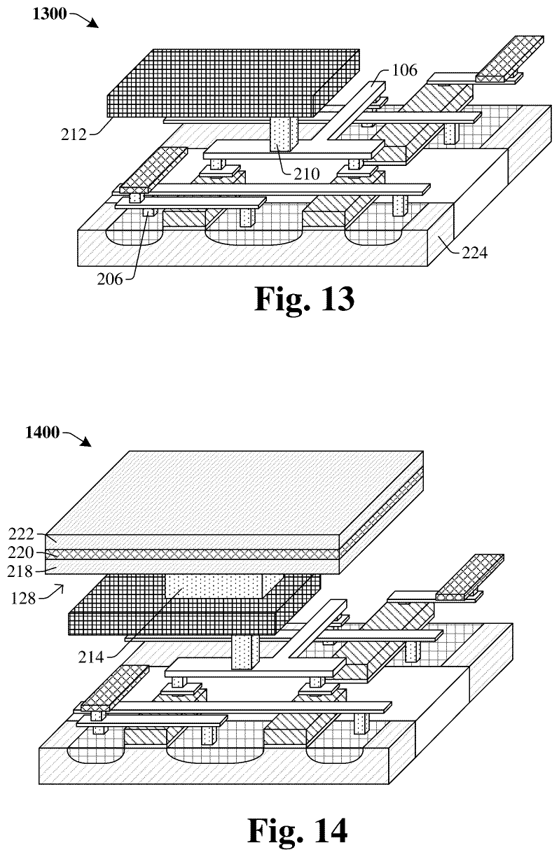

As shown in the three-dimensional view 1300 of FIG. 13, the second via level 210 and the third wire level 212 are formed over the substrate 224. The second via level 210 couples the storage node to the third wire level 212. In some embodiments, the second via level 210 and the third wire level 212 are or comprise a same material as the plurality of contacts 206 and/or the first wire level. In some embodiments, the second via level 210 and the third wire level 212 are formed using a dual damascene process, one or more single damascene processes, or the like.

As shown in the three-dimensional view 1400 of FIG. 14, the third via level 214 and the capacitor 128 are formed over the third wire level 212. The third via level 214 couples the lower electrode 218 of the capacitor 128 to the third wire level 212. In some embodiments, the third via level 214 is or comprises a same material as the plurality of contacts 206 and/or the first wire level. In some embodiments, the third via level 214 and the capacitor 128 are formed using one or more damascene processes, one or more deposition processes (e.g., atomic layer deposition (ALD), chemical vapor deposition (CVD), physical vapor deposition (PVD), etc.) followed by a patterning process, or the like.

That is, the capacitor 128 may be formed by a plurality of deposition processes to form a conformal lower electrode layer, a conformal high-k dielectric layer, and a conformal upper electrode layer. The conformal lower electrode layer, the conformal high-k dielectric layer, and the conformal upper electrode layer are then patterned, resulting in the capacitor 128. In other embodiments, such as the ones depicted in FIGS. 4a-4c, additional dry etching, wet etching, and deposition steps may be used to form a 3D capacitor over the third via level 214.

In some embodiments, the high-k dielectric 220 comprises an amorphous structure when initially deposited. A thermal anneal is performed to turn the amorphous structure into a crystalline high-k dielectric 220. In further embodiments, to form a highly symmetrical crystalline phase with a dielectric constant greater than 35, the conformal upper electrode layer is formed before the thermal anneal is performed. The upper electrode 222 induces additional stress into the high-k dielectric 220 during the thermal anneal. The additional stress results in the material of the high-k dielectric 220 transitioning into a highly symmetrical crystalline phase, such as the cubic phase, the tetragonal phase, or the hexagonal phase.

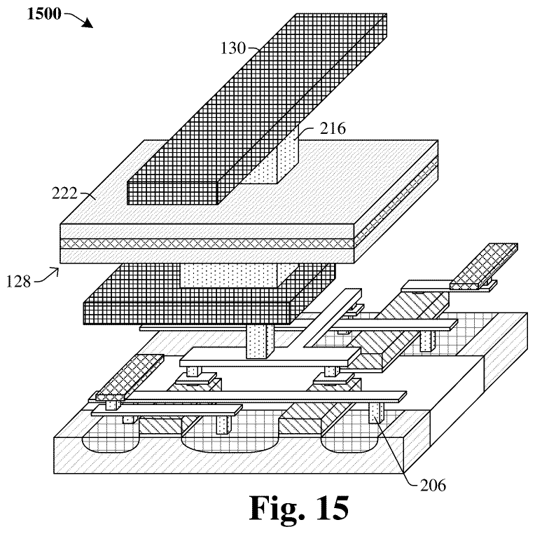

As shown in the three-dimensional view 1500 of FIG. 15, the fourth via level 216 and the ground wire 130 are formed over the capacitor 128. The fourth via level 216 couples the ground wire 130 to the upper electrode 222 of the capacitor 128. In some embodiments, the fourth via level 216 and the ground wire 130 are or comprise a same material as the plurality of contacts 206 and/or the first wire level. In some embodiments, the first via level 208 and the second wire level are formed using a dual damascene process, one or more single damascene processes, or the like.

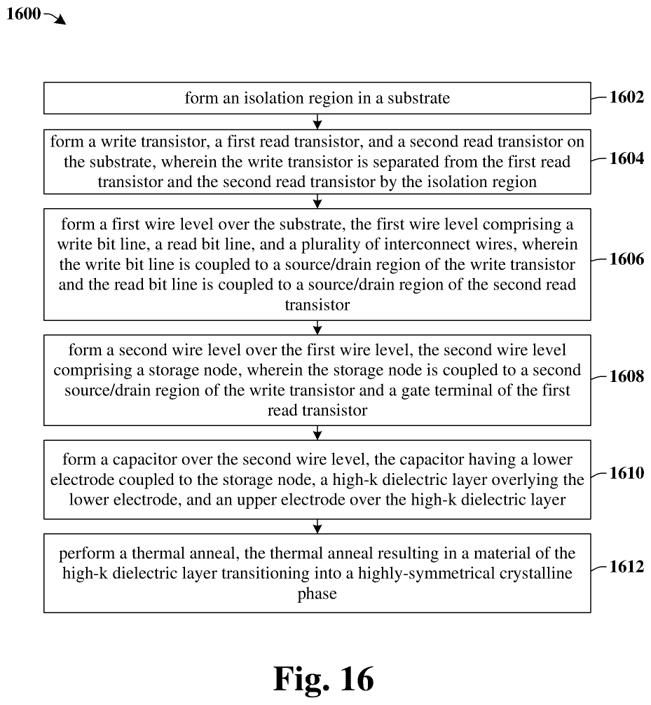

FIG. 16 illustrates a flowchart of some embodiments of a method of forming a GCRAM cell with a capacitor coupled to the storage node. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At 1602, an isolation region is formed in a substrate. See, for example, FIG. 9.

At 1604, a write transistor, a first read transistor, and a second read transistor are formed on the substrate, wherein the write transistor is separated from the first read transistor and the second read transistor by the isolation region. See, for example, FIG. 10.

At 1606, a first wire level is formed over the substrate, the first wire level comprising a write bit line, a read bit line, and a plurality of interconnect wires, wherein the write bit line is coupled to a source/drain region of the write transistor and the read bit line is coupled to a source/drain region of the second read transistor. See, for example, FIGS. 11.

At 1608, a second wire level is formed over the first wire level, the second wire level comprising a storage node, wherein the storage node is coupled to a second source/drain region of the write transistor and a gate terminal of the first read transistor. See, for example, FIG. 12.

At 1610, a capacitor is formed over the second wire level, the capacitor having a lower electrode coupled to the storage node and an upper electrode coupled to a ground wire. See, for example, FIG. 14.

At 1612, a thermal anneal is performed, the thermal anneal resulting in a material of the high-k dielectric layer transitioning into a highly-symmetrical crystalline phase. See, for example, FIG. 14.

The present disclosure describes an integrated capacitor structure coupled to the storage node of a GCRAM device. The capacitor structure provides super high-k dielectric properties by having a highly symmetrical crystalline phase, a maximized area to overlie the transistor structures in the GCRAM, yet a minimized area to be contained within the GCRAM cell boundaries. This provides better GCRAM retention time and power, performance and area (PPA) improvements. Further, the GCRAM device has strategic metal layer routing for spacing improvements. To achieve this, the read word line metals, write bit line metals, read word line metals, and write word line metals may be located in the first two wire levels above the transistor devices (e.g., read bit line and write bit line metals are in the first wire level and read word line and write word line metals are in the second wire level). Each of these read word line metals, write bit line metals, read word line metals, and write word line metals may be global line connections that couple to multiple GCRAM cells. To achieve sufficient thermal budget for crystallization, a lower metal location (e.g., the third or fourth wire levels) is used for the super high-k capacitors such as metal-insulator-metal (MIM) capacitors (e.g., see FIG. 4A). The capacitor structure is strategically located in the lower metal location, for example at the third or fourth wire levels, to increase the thermal budget available for forming the high-k dielectric.

Some embodiments relate to a memory cell, including: a write transistor on a substrate and including a first gate terminal, a first source/drain region, and a second source/drain region coupled to a storage node; a first read transistor on the substrate and including a second gate terminal coupled to the storage node; and a capacitor spaced from the first read transistor and the write transistor and further separated from the substrate by the first read transistor and the write transistor, wherein the capacitor is coupled to the storage node, wherein the memory cell has a first area and the capacitor has a second area, and wherein the ratio of the second area and the first area is equal to or less than 0.8. In some embodiments, the capacitor comprises a high-k dielectric with a dielectric constant greater than 35. In some embodiments, the memory cell further comprises: a second read transistor on the substrate; where the first read transistor, the write transistor, and the second read transistor collectively span a first area when viewed top down, and wherein the capacitor spans a second area when viewed top down that is between 60% and 80% of the first area. In some embodiments, the second read transistor has a third gate terminal extending in a first direction and extending in parallel to the second gate terminal of the first read transistor and wherein the second gate terminal and the third gate terminal are connected to the storage node. In some embodiments, the capacitor comprises an upper electrode, a lower electrode, and a high-k dielectric with a symmetrical crystalline phase. In some embodiments, the symmetrical crystalline phase is a cubic, tetragonal, or hexagonal phase. In some embodiments, the capacitor comprises an upper electrode, a lower electrode, and an insulator between the upper and low electrodes, and wherein the capacitor is a three-dimensional capacitor in which the insulator extends along individual sidewalls of lower and upper electrodes. In some embodiments, the first read transistor further includes a gate dielectric with a first capacitance, where the capacitor has a second capacitance that is over twice the first capacitance. In some embodiments, the memory cell further comprises a conductive wire over the write transistor and the first read transistor, wherein the conductive wire has an L-shaped top geometry and forms the storage node.

Other embodiments relate to an integrated circuit, including: a plurality of memory cells with first areas in a plurality of rows and a plurality of columns, wherein each of the plurality of memory cells includes: a write transistor comprising a first gate terminal, a first source/drain region, and a second source/drain region electrically coupled to a storage node; a first read transistor comprising a second gate terminal electrically coupled to the storage node, a third source/drain region, and a fourth source/drain region; and a capacitor electrically coupled to the storage node, wherein the capacitor has a second area, and wherein the ratio of the second area and a first area of the first areas is equal to or less than 0.8; a write bit line electrically coupled to the first source/drain region for each of the plurality of memory cells in a first column of the plurality of columns; and a write word line electrically coupled to the first gate terminal for each of the plurality of memory cells in a first row of the plurality of rows. In some embodiments, the integrated circuit further includes: a read bit line electrically coupled to the fourth source/drain region for each of the plurality of memory cells in the first column of the plurality of columns; and a read word line electrically coupled to the third source/drain region for each of the plurality of memory cells in the first row of the plurality of rows. In some embodiments, each of the plurality of memory cells has a second read transistor comprising a third gate terminal, a fifth source/drain region electrically coupled to the third source/drain region, and a sixth source/drain region, and wherein the integrated circuit further has: a read bit line electrically coupled to the sixth source/drain region for each of the plurality of memory cells in the first column of the plurality of columns. In some embodiments, the first read transistor is an N-type transistor, and wherein the write transistor is a P-type transistor. In some embodiments, the plurality of memory cells are on a semiconductor substrate and comprise a first memory cell, wherein the write transistor of the first memory cell and the first read transistor of the first memory cell are inset into a top of the semiconductor substrate, and wherein the capacitor of the first memory cell overlies and is spaced from the write transistor of the first memory cell and the first read transistor of the first memory cell. In some embodiments, the plurality of memory cells include a first memory cell, and the capacitor of the first memory cell comprises a high-k dielectric with a dielectric constant greater than 35. In some embodiments, the plurality of memory cells includes a first memory cell that has only three transistors.

Yet other embodiments relate to a method of forming a gain cell random access memory (GCRAM) cell, including: forming an isolation region in a substrate; forming a write transistor, a first read transistor, and a second read transistor on the substrate, wherein the write transistor is separated from the first read transistor and the second read transistor by the isolation region; forming a first wire level over the substrate, the first wire level comprising a write bit line, a read bit line, and a plurality of interconnect wires, wherein the write bit line is coupled to a first source/drain region of the write transistor and the read bit line is coupled to a first source/drain region of the second read transistor; forming a second wire level over the first wire level, the second wire level comprising a storage node, wherein the storage node is coupled to a second source/drain region of the write transistor and a gate terminal of the first read transistor; forming a capacitor over the second wire level, the capacitor having a lower electrode coupled to the storage node, a high-k dielectric layer overlying the lower electrode, and an upper electrode over the high-k dielectric layer; and performing a thermal anneal after forming the capacitor, the thermal anneal resulting in a material of the high-k dielectric layer to transition into a highly-symmetrical crystalline phase. In some embodiments, the first and second read transistors are formed sharing a source/drain region in the substrate. In some embodiments, the storage node is further formed coupled to a gate terminal of the second read transistor. In some embodiments, the method of forming the GCRAM cell further includes forming a third wire level over the second wire level before forming the capacitor, wherein the third wire level contacts a first via extending between the third wire level and the storage node, and wherein the capacitor is formed contacting a second via extending between the third wire level and the lower electrode of the capacitor.

It will be appreciated that in this written description, as well as in the claims below, the terms “first”, “second”, “second”, “third” etc. are merely generic identifiers used for case of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory cell, comprising:
a write transistor on a substrate and comprising a first gate terminal, a first source/drain region, and a second source/drain region coupled to a storage node;
a first read transistor on the substrate and comprising a second gate terminal coupled to the storage node; and
a capacitor spaced from the first read transistor and the write transistor and further separated from the substrate by the first read transistor and the write transistor, wherein the capacitor is coupled to the storage node, wherein the memory cell has a first area and the capacitor has a second area, and wherein a ratio of the second area and the first area is equal to or less than 0.8.

2. The memory cell of claim 1, wherein the capacitor comprises a high-k dielectric with a dielectric constant greater than 35.

3. The memory cell of claim 1, further comprising:
a second read transistor on the substrate;
wherein the first area is defined by the span of a memory cell region containing the first read transistor, the write transistor, and the second read transistor when viewed from a top down perspective, wherein the second area is defined by the span of the capacitor when viewed from a top down perspective, and wherein the second area is between 60% and 80% of the first area.

4. The memory cell of claim 3, wherein the second read transistor has a third gate terminal extending in a first direction and extending in parallel to the second gate terminal of the first read transistor and wherein the second gate terminal and the third gate terminal are connected to the storage node.

5. The memory cell of claim 1, wherein the capacitor comprises an upper electrode, a lower electrode, and a high-k dielectric with a symmetrical crystalline phase.

6. The memory cell of claim 5, wherein the symmetrical crystalline phase is a cubic, tetragonal, or hexagonal phase.

7. The memory cell of claim 1, wherein the capacitor comprises an upper electrode, a lower electrode, and an insulator between the upper electrode and the lower electrode, and wherein the capacitor is a three-dimensional capacitor in which the insulator extends along individual sidewalls of lower and upper electrodes.

8. The memory cell of claim 1, wherein the first read transistor further comprises a gate dielectric with a first capacitance, and wherein the capacitor has a second capacitance that is over twice the first capacitance.

9. The memory cell according to claim 1, further comprising:
a conductive wire over the write transistor and the first read transistor, wherein the conductive wire has an L-shaped top geometry and forms the storage node.

10. An integrated circuit, comprising:
a plurality of memory cells with first areas in a plurality of rows and a plurality of columns, wherein each of the plurality of memory cells comprises:
a write transistor comprising a first gate terminal, a first source/drain region, and a second source/drain region electrically coupled to a storage node;
a first read transistor comprising a second gate terminal electrically coupled to the storage node, a third source/drain region, and a fourth source/drain region; and
a capacitor electrically coupled to the storage node, wherein the capacitor has a second area, and wherein a ratio of the second area to a first area of the first areas is equal to or less than 0.8;
a write bit line electrically coupled to the first source/drain region for each of the plurality of memory cells in a first column of the plurality of columns; and
a write word line electrically coupled to the first gate terminal for each of the plurality of memory cells in a first row of the plurality of rows.

11. The integrated circuit according to claim 10, further comprising:
a read bit line electrically coupled to the fourth source/drain region for each of the plurality of memory cells in the first column of the plurality of columns; and
a read word line electrically coupled to the third source/drain region for each of the plurality of memory cells in the first row of the plurality of rows.

12. The integrated circuit according to claim 10, wherein each of the plurality of memory cells comprises a second read transistor comprising a third gate terminal, a fifth source/drain region electrically coupled to the third source/drain region, and a sixth source/drain region, and wherein the integrated circuit further comprises:
a read bit line electrically coupled to the sixth source/drain region for each of the plurality of memory cells in the first column of the plurality of columns.

13. The integrated circuit according to claim 10, wherein the first read transistor is an N-type transistor, and wherein the write transistor is a P-type transistor.

14. The integrated circuit according to claim 10, wherein the plurality of memory cells are on a semiconductor substrate and comprise a first memory cell, wherein the write transistor of the first memory cell and the first read transistor of the first memory cell are inset into a top of the semiconductor substrate, and wherein the capacitor of the first memory cell overlies and is spaced from the write transistor of the first memory cell and the first read transistor of the first memory cell.

15. The integrated circuit according to claim 10, wherein the plurality of memory cells comprise a first memory cell, and wherein the capacitor of the first memory cell comprises a high-k dielectric with a dielectric constant greater than 35.

16. The integrated circuit according to claim 10, wherein the plurality of memory cells comprises a first memory cell that has only three transistors.

17. A method of forming a gain cell random access memory cell, comprising:
forming an isolation region in a substrate;
forming a write transistor, a first read transistor, and a second read transistor on the substrate, wherein the write transistor is separated from the first read transistor and the second read transistor by the isolation region;
forming a first wire level over the substrate, the first wire level comprising a write bit line, a read bit line, and a plurality of interconnect wires, wherein the write bit line is coupled to a first source/drain region of the write transistor and the read bit line is coupled to a first source/drain region of the second read transistor;
forming a second wire level over the first wire level, the second wire level comprising a storage node, wherein the storage node is coupled to a second source/drain region of the write transistor and a gate terminal of the first read transistor; and
forming a capacitor over the second wire level, the capacitor having a lower electrode coupled to the storage node, a high-k dielectric layer overlying the lower electrode, and an upper electrode over the high-k dielectric layer; and
performing a thermal anneal after forming the capacitor, the thermal anneal resulting in a material of the high-k dielectric layer transitioning into a highly-symmetrical crystalline phase.

18. The method of claim 17, wherein the first and second read transistors are formed sharing a source/drain region in the substrate.

19. The method of claim 17, wherein the storage node is further formed coupled to a gate terminal of the second read transistor.

20. The method of claim 17, further comprising:
forming a third wire level over the second wire level before forming the capacitor, wherein the third wire level contacts a first via extending between the third wire level and the storage node, and wherein the capacitor is formed contacting a second via extending between the third wire level and the lower electrode of the capacitor.
